(19) United States
(12) Patent Application Publication
(10) Pub. No.: US 2026/0231796 A1
(43) Pub. Date: Aug. 6, 2026

(54) CORELESS INTERPOSER, MANUFACTURING METHOD THEREOF, AND SEMICONDUCTOR PACKAGE INCLUDING THE SAME

(71) Applicant: SAMSUNG ELECTRO-MECHANICS CO., LTD., Suwon-si (KR)

(72) Inventors: Sanghoon Kim, Suwon-si, Gyeonggi-do (KR); Kyunghwan Ko, Suwon-si, Gyeonggi-do (KR); Jinuk Lee, Suwon-si, Gyeonggi-do (KR); Chanhoon Ko, Suwon-si, Gyeonggi-do (KR); Hyojin Cha, Suwon-si, Gyeonggi-do (KR); Woodeug Park, Suwon-si, Gyeonggi-do (KR)

(73) Assignee: SAMSUNG ELECTRO-MECHANICS CO., LTD., Suwon-si (KR)

(21) Appl. No.: 19/271,390

(22) Filed: Jul. 16, 2025

(30) Foreign Application Priority Data
Feb. 3, 2025 (KR) 10-2025-0012938

(51) Int. Cl. H01L 23/538; H01L 21/48

(52) U.S. Cl. CPC H10W 70/65; H10W 70/05; H10W 70/611; H10W 70/685

(57) ABSTRACT

A coreless interposer is disclosed that includes a coreless substrate having multiple insulating layers and coreless circuit wires embedded within the insulating layers. A bridge substrate is embedded within the coreless substrate. The bridge substrate includes an insulating layer made of an organic compound and multiple bridge circuit wires disposed within the insulating layer. The bridge circuit wires have a smaller wiring width than the coreless circuit wires. An uppermost bridge circuit wire is embedded within the bridge insulating layer.

### CROSS-REFERENCE TO RELATED APPLICATION

This application claims priority to and the benefit of Korean Patent Application No. 10-2025-0012938 filed with the Korean Intellectual Property Office on Feb. 3, 2025, the entire contents of which are incorporated herein by reference.

### BACKGROUND

### 1. Field

The present disclosure relates to a coreless interposer, a manufacturing method thereof, and a semiconductor package including the same.

### 2. Description of the Related Art

A high performance device such as a high performance CPU or an AI accelerator requires high processing performance and data processing ability. Therefore, a technology that effectively connects high performance devices and performs high performance packaging of the connected high performance devices is being developed.

For example, a 2.5D packaging technology is a technology that horizontally disposes semiconductor chips and uses a Si interposer to connect them. The 2.5D packaging technology maximizes performance of devices by making electrical connection between the semiconductor chips more efficient and facilitating integration of a chiplet and a memory.

In addition, SWIFT is a technology that performs packaging using a rear distribution layer (RDL) technology that enables connection with the outside by adding a wiring layer to a back surface of a semiconductor chip in a final stage of a manufacturing process of the semiconductor chip, and enables high-speed data transmission.

In addition, an embedded multi-die interconnect bridge (EMIB) packaging technology is a technology that forms a bridge substrate that includes an ultra-fine circuit layer on a silicon substrate to connect multiple chips. The EMIB packaging technology is a technology that embeds a semiconductor chip in a cavity formed at an upper end of the substrate and electrically connects a bump of the semiconductor chip and a circuit wire of the silicon substrate, and enables high-speed data transmission, low electric power consumption, and high-integration packaging.

### SUMMARY

Embodiments are intended to provide a coreless interposer capable of easily implementing a thin type, minimizing warpage, and simultaneously easily implementing an ultra-fine circuit, a manufacturing method thereof, and a semiconductor package including the same.

However, problems to be solved by the embodiments are not limited to the above-described problem and may be variously extended in a range of technical ideas included in the embodiments.

A coreless interposer according to an embodiment of the present disclosure includes: a coreless substrate that includes a plurality of insulating layers and a plurality of coreless circuit wires disposed within the plurality of insulating layers; and a bridge substrate that is disposed within the coreless substrate. The bridge substrate includes a bridge insulating layer including an organic compound and a plurality of bridge circuit wires disposed within the bridge insulating layer and having a wiring width less than that of the plurality of coreless circuit wires, and an uppermost bridge circuit wire among the plurality of bridge circuit wires is embedded in the bridge insulating layer.

An upper surface of the uppermost bridge circuit wire may be disposed on the same plane as that of an upper surface of the bridge substrate.

A lowermost bridge circuit wire among the plurality of bridge circuit wires may be a conductive pad protruding from a lower surface of the bridge substrate.

The plurality of insulating layers may include an uppermost insulating layer, a lowermost insulating layer, and an intermediate insulating layer disposed between the uppermost insulating layer and the lowermost insulating layer, and the bridge substrate may be disposed within the uppermost insulating layer.

The uppermost insulating layer may not include a glass cloth, and the intermediate insulating layer may include a glass cloth.

The coreless interposer may further include an adhesive member disposed on the upper surface of the bridge substrate. An upper surface of the adhesive member may be disposed on the same plane as that of an upper surface of the uppermost insulating layer.

The coreless interposer may further include a bump pad disposed above the adhesive member and electrically connected to the uppermost bridge circuit wire.

The coreless interposer may further include a first bridge via that penetrates the adhesive member and electrically connects the bump pad and the uppermost bridge circuit wire.

The coreless interposer may further include a second bridge via that penetrates the uppermost insulating layer and electrically connects an intermediate coreless circuit wire disposed between an uppermost coreless circuit wire and a lowermost coreless circuit wire among the plurality of coreless circuit wires and the lowermost bridge circuit wire.

The coreless interposer may further include a solder resist pattern that covers the uppermost coreless circuit wire and the uppermost insulating layer. The bump pad may protrude from an upper surface of the solder resist pattern.

The bridge substrate may further include a dummy member, and the dummy member may include a dummy insulating layer covering the uppermost bridge circuit wire and made of the same material as that of the bridge insulating layer and a dummy wiring layer embedded in the dummy insulating layer, not electrically connected to the uppermost bridge circuit wire, and including a plurality of first penetration holes.

The first bridge via may penetrate the plurality of first penetration holes.

The coreless interposer may further include a protective member that covers the adhesive member and includes a plurality of second penetration holes. The first bridge via may penetrate the plurality of second penetration holes.

The coreless interposer may further include: a solder resist pattern that covers the adhesive member, an uppermost coreless circuit wire, and the uppermost insulating layer; and a bump pad that is disposed on the solder resist pattern and is electrically connected to the uppermost bridge circuit wire.

The coreless interposer may further include: a first bump pad that is disposed on the adhesive member and is electrically connected to the uppermost bridge circuit wire; a solder resist pattern that covers the first bump pad and the uppermost insulating layer; and a second bump pad that is disposed on the solder resist pattern and is electrically connected to the first bump pad.

A manufacturing method of a coreless interposer according to an embodiment includes: preparing a bridge substrate that includes a bridge insulating layer including an organic compound and a plurality of bridge circuit wires disposed within the bridge insulating layer; adhering the bridge substrate to a carrier substrate using an adhesive member; forming a coreless substrate that covers the bridge substrate and includes a plurality of coreless circuit wires having a wiring width greater than that of the plurality of bridge circuit wires; and separating a portion of the carrier substrate from the coreless substrate. An uppermost bridge circuit wire among the plurality of bridge circuit wires is embedded in the bridge insulating layer.

The manufacturing method may further include forming a seed circuit wire using a seed layer of the carrier substrate before the bridge substrate is adhered to the carrier substrate.

The manufacturing method may further include: forming a bump pad that is connected to the bridge circuit wire of the bridge substrate on the coreless substrate; removing the seed layer; forming a solder resist pattern covering the bump pad on the coreless substrate; and removing a portion of a solder resist layer to expose the bump pad.

The forming of the coreless substrate covering the bridge substrate may include: forming the bridge substrate and an uppermost insulating layer covering the seed circuit wire; and stacking an intermediate insulating layer covering the uppermost insulating layer and a lowermost insulating layer. The bridge substrate may be disposed within the uppermost insulating layer

A semiconductor package according to an embodiment includes: a circuit board; a plurality of semiconductor chips that are disposed above the circuit board; and a coreless interposer that electrically connects the circuit board and the plurality of semiconductor chips. The coreless interposer includes a coreless substrate including a plurality of insulating layers and a plurality of coreless circuit wires disposed within the plurality of insulating layers and a bridge substrate disposed within the coreless substrate, the bridge substrate includes a bridge insulating layer including an organic compound and a plurality of bridge circuit wires disposed within the bridge insulating layer and having a wiring width less than that of the plurality of coreless circuit wires, and an uppermost bridge circuit wire among the plurality of bridge circuit wires is embedded in the bridge insulating layer.

According to embodiments, a coreless interposer may include a coreless substrate that does not include a separate core member so that a thinner coreless interposer is implemented.

In addition, semiconductor chips may be connected to each other inside the coreless substrate or a bridge substrate including a photosensitive organic compound may be disposed at a portion connecting the semiconductor chip to a memory. Thus, an ultra-fine circuit may be implemented within the coreless interposer with the bridge substrate and at the same time a mechanical property such as a modulus and a coefficient of thermal expansion (CTE) between the coreless substrate and the bridge substrate may be similar so that warpage or the like of the coreless interposer is minimized.

In addition, because the bridge substrate includes the photosensitive organic compound and does not include silicon, the bridge substrate with a thin thickness such as 15 to 30 nm may be implemented.

It is obvious that an effect of embodiments is not limited to the above-described effect and may be variously extended without departing from the spirit and scope of the present disclosure.

### BRIEF DESCRIPTION OF THE DRAWINGS

FIG. 1 is a cross-sectional view of a coreless interposer according to an embodiment.

FIG. 2 is a schematic flowchart of a manufacturing method of the coreless interposer according to an embodiment.

FIGS. 3 to 11 are cross-sectional views sequentially illustrating a manufacturing method of the coreless interposer according to an embodiment.

FIG. 12 is a cross-sectional view of a coreless interposer according to another embodiment.

FIG. 13 is a plan view of a bridge substrate of FIG. 12.

FIG. 14 is a cross-sectional view of a coreless interposer according to another embodiment.

FIG. 15 is a plan view of a protective member of FIG. 14.

FIG. 16 is a cross-sectional view of a coreless interposer according to another embodiment.

FIG. 17 is a cross-sectional view of a coreless interposer according to another embodiment.

FIG. 18 is a side view of a semiconductor package according to an embodiment.

### DETAILED DESCRIPTION OF THE EMBODIMENTS

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, the accompanying drawings are provided only in order to allow embodiments disclosed in the present specification to be easily understood and should not be interpreted as limiting a technical idea disclosed in the present specification, and it should be understood that the present disclosure includes all modifications, equivalents, and substitutions without departing from the spirit and technical range of the present disclosure.

In the drawings, each element's size and thickness are arbitrarily illustrated for ease of description, but the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

Throughout the specification, “connected” does not mean only when two or more constituent elements are directly connected, but also when two or more constituent elements are indirectly connected through another constituent element, or when they are physically connected or electrically connected, and it may include a case in which substantially integral parts are connected to each other although they are referred to by different names according to positions or functions.

Hereinafter, various embodiments and variations will be described in detail with reference to the drawings.

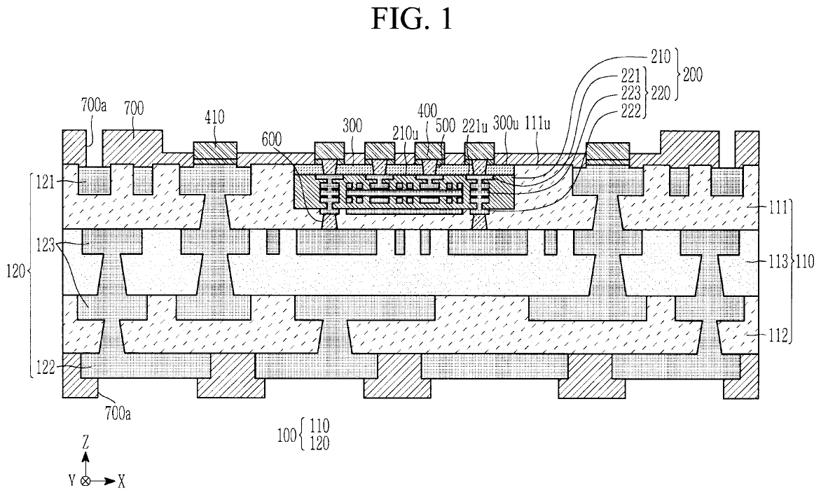

FIG. 1 is a cross-sectional view of a coreless interposer according to an embodiment.

As shown in FIG. 1, the coreless interposer according to the embodiment may include a coreless substrate 100, a bridge substrate 200, an adhesive member 300, a bump pad 400, a first bridge via 500, a second bridge via 600, and a solder resist pattern 700.

The coreless substrate 100 may include a plurality of insulating layers 110 and a plurality of coreless circuit wires 120.

The plurality of insulating layers 110 may include an uppermost insulating layer 111, a lowermost insulating layer 112, and an intermediate insulating layer 113. Here, an upper and lower positional relationship may be set based on a Z-direction. That is, a positional relationship such as an uppermost portion, a lowermost portion, an upper surface, or a lower surface may be set based on the Z-direction.

The uppermost insulating layer 111 may be disposed at an uppermost portion based on the Z-direction among the plurality of insulating layers. The uppermost insulating layer 111 may include a thermosetting resin such as an epoxy resin or polyimide, or a thermoplastic resin such as polyethylene (PE), polycarbonate (PC), or polyvinyl chloride (PVC), and a glass cloth may not be included within the thermosetting resin or the thermoplastic resin. Therefore, the uppermost insulating layer 111 may be made of an ajinomoto buildup film (ABF), a resin coated copper (RCC), or the like.

The lowermost insulating layer 112 may be disposed at a lowermost portion based on the Z-direction among the plurality of insulating layers. The lowermost insulating layer 112 may include a thermosetting resin or a thermoplastic resin, and a glass cloth may or may not be included within the thermosetting resin or the thermoplastic resin. Therefore, the lowermost insulating layer 112 may be made of an ajinomoto buildup film (ABF), a prepreg, or the like.

The intermediate insulating layer 113 may be disposed between the uppermost insulating layer 111 and the lowermost insulating layer 112. The intermediate insulating layer 113 may include a thermosetting resin or a thermoplastic resin, and a glass cloth may be included within at least a portion of the intermediate insulating layer 113. Therefore, at least a portion of the intermediate insulating layer 113 may be made of a prepreg, a glass cloth primer (GCP), or the like.

In the present embodiment, the coreless substrate 100 may be formed of one intermediate insulating layer 113, but the present disclosure is not necessarily limited thereto, and an embodiment in which the coreless substrate 100 includes a plurality of intermediate insulating layers 113 may be possible.

That is, the lowermost insulating layer 112 and at least a portion of the intermediate insulating layer 113 may include a glass cloth, so that the coreless substrate has a minimal strength and a minimal rigidity.

The plurality of coreless circuit wires 120 may be disposed inside the plurality of insulating layers 110, and may transfer an electrical signal. The plurality of coreless circuit wires 120 may be disposed in various patterns. The plurality of coreless circuit wires 120 may include a conductive material such as copper (Cu), aluminum (Al), silver (Ag), tin (Sn), gold (Au), nickel (Ni), lead (Pb), titanium (Ti), or an alloy thereof.

The plurality of coreless circuit wires 120 may include an uppermost coreless circuit wire 121, a lowermost coreless circuit wire 122, and an intermediate coreless circuit wire 123.

The uppermost coreless circuit wire 121 may be disposed at an uppermost portion based on the Z-direction among the plurality of coreless circuit wires 120, the lowermost coreless circuit wire 122 may be disposed at a lowermost portion based on the Z-direction among the plurality of coreless circuit wires 120, and the intermediate coreless circuit wire 123 may be disposed between the uppermost coreless circuit wire 121 and the lowermost coreless circuit wire 122. Here, for ease of description, each of the uppermost coreless circuit wire 121, the lowermost coreless circuit wire 122, and the intermediate coreless circuit wire 123 is shown in the drawings as including a via layer, and in the present embodiment, the intermediate coreless circuit wire 123 may be formed of two layers, but the present disclosure is not necessarily limited thereto, and the intermediate coreless circuit wire 123 may be formed of various numbers of layers. In addition, the lowermost coreless circuit wire 122 and the intermediate coreless circuit wire 123 may be formed by a plating process and a lithography process so that they include a seed layer for the plating process, but the seed layer may be omitted in the drawings for ease of description.

The bridge substrate 200 may be disposed inside the coreless substrate 100. That is, the bridge substrate 200 may be disposed within the plurality of insulating layers 110 of the coreless substrate 100. More specifically, the bridge substrate 200 may be disposed within the uppermost insulating layer 111 among the plurality of insulating layers 110. The bridge substrate 200 may be disposed inside the coreless substrate 100 to implement an ultra-fine circuit.

The bridge substrate 200 may include a bridge insulating layer 210 and a plurality of bridge circuit wires 220.

The bridge insulating layer 210 may include an organic compound. For example, the bridge insulating layer 210 may be made of a photosensitive organic compound such as a photo imageable dielectric (PID).

The plurality of bridge circuit wires 220 may be disposed inside the bridge insulating layer 210, and may have a wiring width smaller than a wiring width of the plurality of coreless circuit wires 120.

The plurality of bridge circuit wires 220 may transfer an electrical signal, and may be disposed in various patterns. The plurality of bridge circuit wires 220 may include a conductive material such as copper (Cu), aluminum (Al), silver (Ag), tin (Sn), gold (Au), nickel (Ni), lead (Pb), titanium (Ti), or an alloy thereof.

The plurality of bridge circuit wires 220 may include an uppermost bridge circuit wire 221, a lowermost bridge circuit wire 222, and an intermediate bridge circuit wire 223.

The uppermost bridge circuit wire 221 may be disposed at an uppermost portion based on the Z-direction among the plurality of bridge circuit wires 220, and may be embedded (or buried) in the bridge insulating layer 210.

In this case, an upper surface 221a of the uppermost bridge circuit wire 221 may be disposed on the same plane (e.g., an XY plane) as that of an upper surface 210u of the bridge insulating layer 210 that is an upper surface of the bridge substrate 200.

The lowermost bridge circuit wire 222 may be disposed at a lowermost portion based on the Z-direction among the plurality of bridge circuit wires 220, and may be a conductive pad protruding from a lower surface of the bridge substrate.

The intermediate bridge circuit wire 223 may be disposed between the uppermost bridge circuit wire 221 and the lowermost bridge circuit wire 222.

The bridge substrate 200 disposed inside the coreless substrate 100 may not include silicon and may include an organic compound, so that film thinning of the bridge substrate 200 is possible.

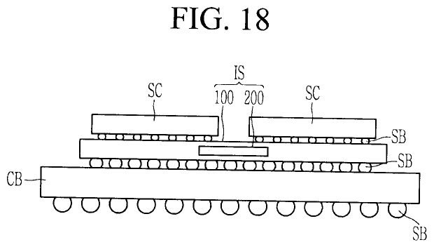

In addition, because the bridge substrate 200 disposed inside the coreless substrate 100 includes the organic compound, an ultra-fine circuit may be implemented within a coreless interposer IS of FIG. 18 with the bridge substrate 200 and simultaneously a mechanical property such as a modulus and a coefficient of thermal expansion (CTE) between the coreless substrate 100 and the bridge substrate 200 may be similar so that warpage or the like of the coreless interposer IS is minimized.

The adhesive member 300 may be disposed on an upper surface of the bridge substrate 200. The adhesive member 300 may be used to adhere the bridge substrate 200 to a carrier substrate CS during a manufacturing process of the coreless interposer IS.

In this case, an upper surface 300u of the adhesive member 300 may be disposed on the same plane as that of an upper surface 111u of the uppermost insulating layer 111.

The bump pad 400 may be disposed above the adhesive member 300, and may be electrically connected to the uppermost bridge circuit wire 221 through the first bridge via 500. The bump pad 400 may electrically connect the bridge substrate 200 and a semiconductor chip SC of FIG. 18. A coreless pad 410 electrically connected to the uppermost coreless circuit wire 121 may be disposed on the same layer as that of the bump pad 400. The bump pad 400 and the coreless pad 410 may be made of a material such as copper.

The first bridge via 500 may penetrate the adhesive member 300, and may electrically connect the bump pad 400 to the uppermost bridge circuit wire 221. The first bridge via 500 may be made of the same material as those of the plurality of coreless circuit wires 120, and may include a conductive material such as copper (Cu), aluminum (Al), silver (Ag), tin (Sn), gold (Au), nickel (Ni), lead (Pb), titanium (Ti), or an alloy thereof.

The second bridge via 600 may penetrate the uppermost insulating layer 111. The second bridge via 600 may connect the intermediate coreless circuit wire 123 embedded in the intermediate insulating layer 113 and the lowermost bridge circuit wire 222. The second bridge via 600 may be made of the same material as those of the plurality of coreless circuit wires 120, and may include a conductive material such as copper (Cu), aluminum (Al), silver (Ag), tin (Sn), gold (Au), nickel (Ni), lead (Pb), titanium (Ti), or an alloy thereof.

The solder resist pattern 700 may cover the uppermost coreless circuit wire 121, the uppermost insulating layer 111, and the adhesive member 300. The solder resist pattern 700 may include an insulating material such as a solder resist.

In this case, the bump pad 400 may protrude from an upper surface of the solder resist pattern 700. Therefore, the bump pad 400 protruding outward without being covered by the solder resist pattern 700 may be in contact with the semiconductor chip SC.

The coreless interposer IS according to the present embodiment having the structure may implement the coreless interposer IS with a thinner thickness by including the coreless substrate 100 that does not include a separate core member.

In addition, because the bridge substrate 200 including the organic compound is disposed inside the coreless substrate 100, an ultra-fine circuit may be implemented inside the coreless interposer IS with the bridge substrate 200 and simultaneously a mechanical property such as a modulus and a coefficient of thermal expansion (CTE) between the coreless substrate 100 and the bridge substrate 200 may be similar so that warpage or the like of the coreless interposer IS is minimized.

In addition, because the bridge substrate 200 includes the organic compound and does not include the silicon, the bridge substrate 200 with a thin thickness such as 15 to 30 nm may be implemented.

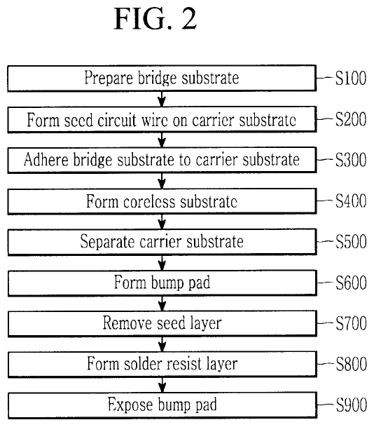

Then, a manufacturing method of the coreless interposer according to an embodiment will be described in detail with reference to FIGS. 2 to 11 together with FIG. 1.

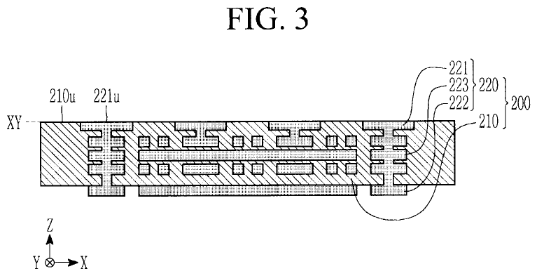

FIG. 2 is a schematic flowchart of a manufacturing method of the coreless interposer according to an embodiment, and FIGS. 3 to 11 are cross-sectional views sequentially illustrating a manufacturing method of the coreless interposer according to an embodiment.

As shown in FIG. 2 and FIG. 3, the bridge substrate 200 may be prepared (S100). The bridge substrate 200 may be formed by the following process.

The bridge insulating layer 210 including an organic compound may be formed on a bridge carrier substrate (not shown), a bridge via hole may be formed in the bridge insulating layer 210, and then the bridge circuit wire 220 may be formed in the bridge via hole by a method such as a plating process. The bridge insulating layer 210 and the bridge circuit wire 220 may be stacked by repeating the process, and then the bridge carrier substrate may be separated to complete the bridge substrate 200.

In this case, the bridge circuit wire 220 may be stacked in an order of the uppermost bridge circuit wire 221, the intermediate bridge circuit wire 223, and the lowermost bridge circuit wire 222 on the bridge carrier substrate. Thus, if the bridge carrier substrate is separated from the bridge substrate 200 and the bridge substrate 200 is turned over, the uppermost bridge circuit wire 221 may be embedded in the bridge insulating layer 210, and the lowermost bridge circuit wire 222 may protrude from a surface of the bridge insulating layer 210.

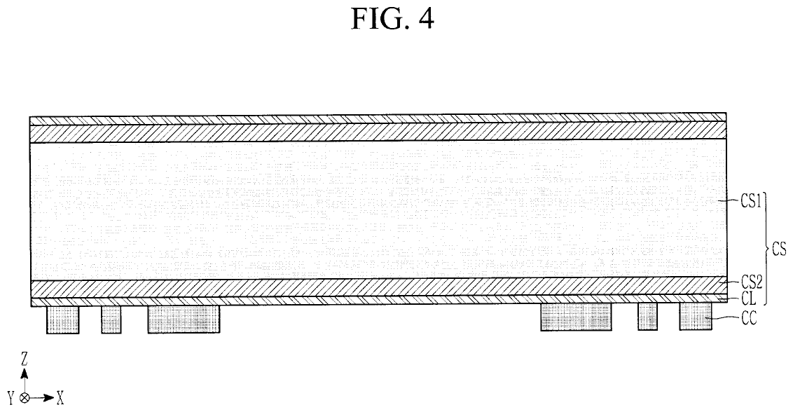

Next, as shown in FIG. 2 and FIG. 4, a seed circuit wire CC may be formed on the carrier substrate CS (S200). The carrier substrate CS may include a conductive thin film CS2 and a seed layer CL sequentially stacked on both surfaces of a carrier main body CS1. The conductive thin film CS2 and the seed layer CL may be a copper foil layer. The seed circuit wire CC may be formed on the seed layer CL by a plating process and a lithography process. The seed circuit wire CC may remain in the coreless substrate 100 in a subsequent process to become the uppermost coreless circuit wire 121.

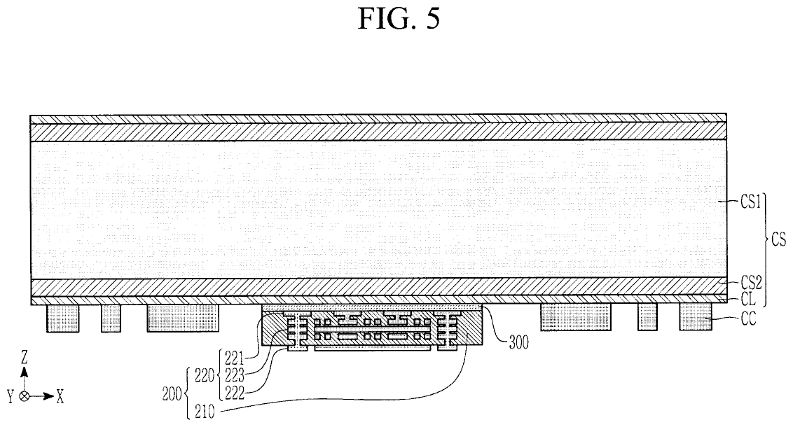

In FIG. 4, the seed circuit wire CC is shown as being formed on one surface of the carrier substrate CS, but the seed circuit wire CC may also be formed on a surface facing the one surface. The seed circuit wire CC may be formed on both surfaces of the carrier substrate CS in processes to be described below with reference to FIGS. 5 to 7.

Next, as shown in FIG. 2 and FIG. 5, the bridge substrate 200 may be adhered to the carrier substrate CS using the adhesive member 300 (S300).

Next, as shown in FIGS. 2, 6, and 7, the coreless substrate 100 may be formed (S400). The coreless substrate 100 may cover the bridge substrate 200. The coreless substrate 100 may include the plurality of insulating layers 110 and the plurality of coreless circuit wires 120.

The plurality of insulating layers 110 may include the uppermost insulating layer 111, the lowermost insulating layer 112, and the intermediate insulating layer 113. The plurality of coreless circuit wires 120 may include the uppermost coreless circuit wire 121 corresponding to the seed circuit wire CC, the lowermost coreless circuit wire 122, and the intermediate coreless circuit wire 123.

Hereinafter, a process of forming the coreless substrate 100 will be described in detail with reference to the drawings.

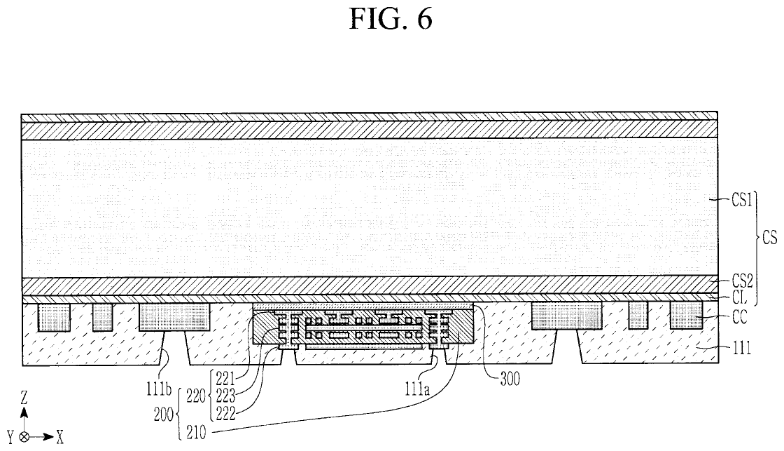

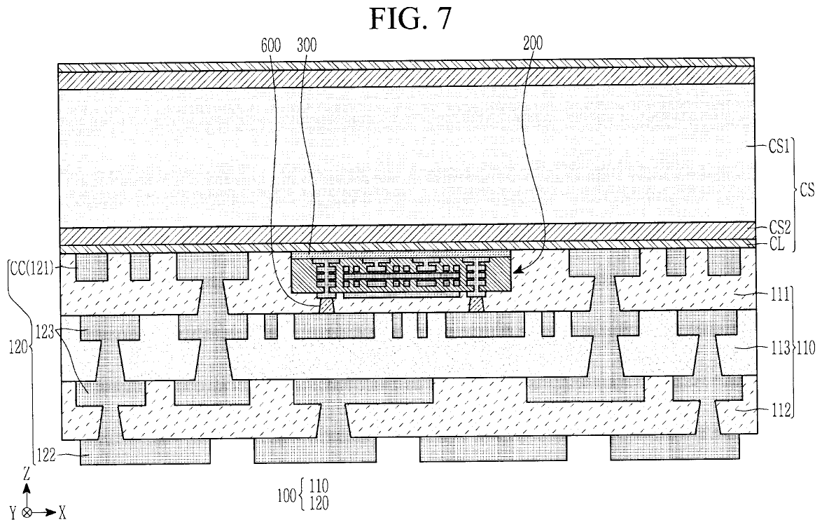

First, as shown in FIG. 6, the uppermost insulating layer 111 covering the bridge substrate 200 and the seed circuit wire CC may be formed above a surface of the seed layer CL. The seed circuit wire CC may become the uppermost coreless circuit wire 121 in a subsequent process. Then, a via hole 111a exposing a portion of the lowermost bridge circuit wire 222 and another via hole 111b exposing a portion of the seed circuit wire CC may be formed in the uppermost insulating layer 111. Then, as shown in FIG. 7, the via holes 111a and 111b of the uppermost insulating layer 111 may be filled using a plating process and a lithography process to form a second bridge via 600, another via, and the intermediate coreless circuit wire 123. Then, the intermediate insulating layer 113 covering the intermediate coreless circuit wire 123 and the lowermost insulating layer 112 may be sequentially formed. Then, a via hole exposing a portion of the intermediate coreless circuit wire 123 may be formed in the lowermost insulating layer 112, and the via hole may be filled using a plating process and a lithography process to form a via and the lowermost coreless circuit wire 122. Thus, the coreless substrate 100 may be completed. Here, the bridge substrate 200 may be disposed within the uppermost insulating layer 111.

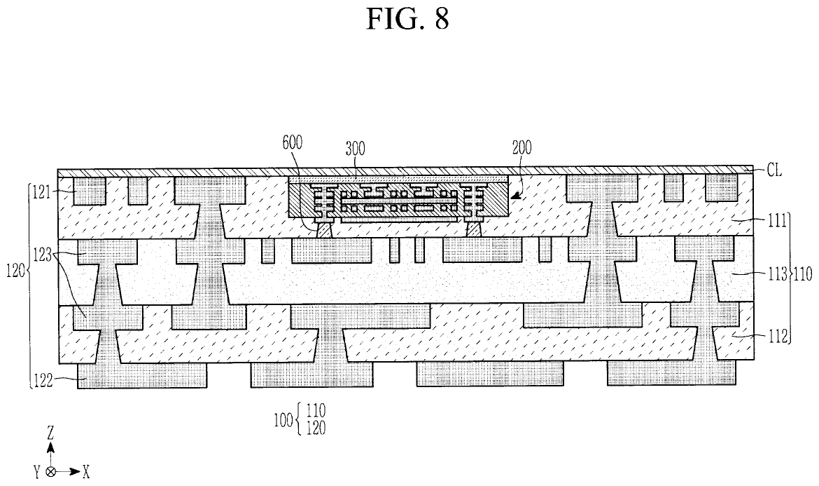

Next, as shown in FIG. 2 and FIG. 8, only the carrier main body CS1 and the conductive thin film CS2 of the carrier substrate CS may be separated from the coreless substrate 100 (S500). Therefore, only the seed layer CL may remain on a surface of the coreless substrate 100.

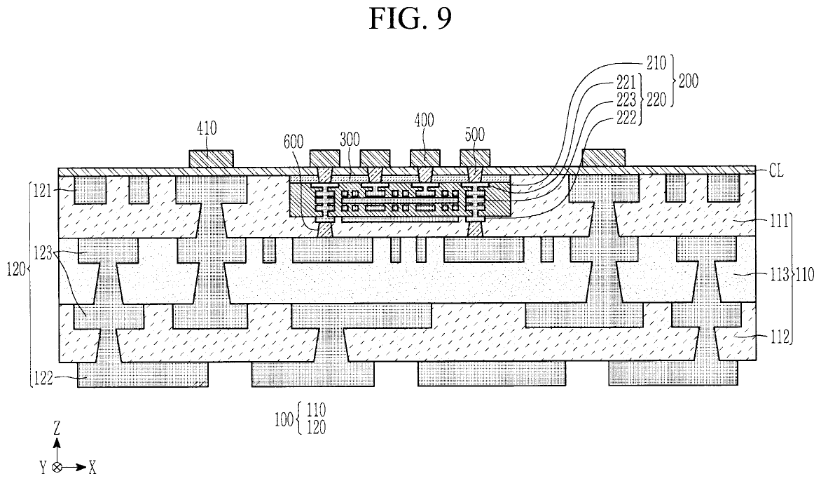

Next, as shown in FIG. 2 and FIG. 9, a via hole exposing the uppermost bridge circuit wire 221 may be formed in the adhesive member 300 and the seed layer CL. In this case, the via hole may be processed by simultaneously processing the adhesive member 300 and the seed layer CL with a laser having an output of the same size or by processing the adhesive member 300 and the seed layer CL with lasers having outputs of different sizes. Then, the first bridge via 500 may be formed using a plating process in the via hole, and the bump pad 400 may be formed at a position corresponding to the first bridge via 500 above the coreless substrate 100 (S600). In this case, the coreless pad 410 corresponding to a portion of the uppermost coreless circuit wire 121 may be formed above the coreless substrate 100 in the same layer as that of the bump pad 400. The bump pad 400 and the coreless pad 410 may be made of a material such as copper.

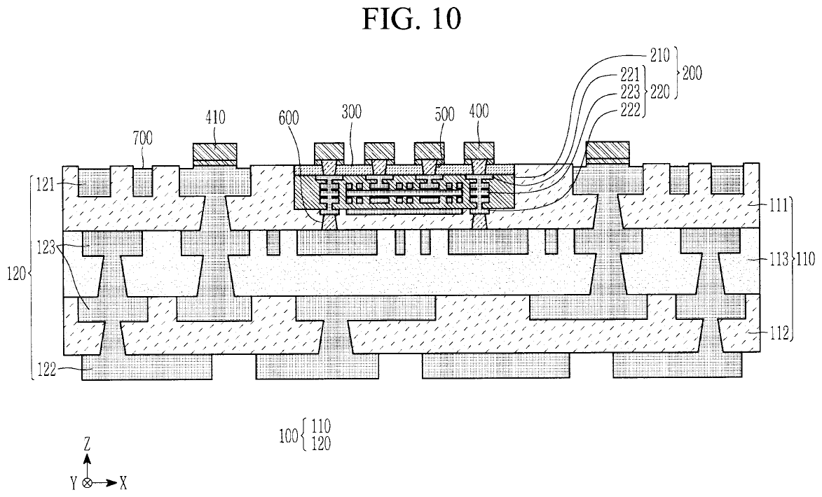

Next, as shown in FIG. 2 and FIG. 10, the seed layer CL may be removed from the coreless substrate 100 using an etching process (S700). In this case, the seed layer CL disposed below the bump pad 400 and the coreless pad 410 may remain without being removed. In the etching process for removing the seed layer CL, a portion of a surface of the uppermost coreless circuit wire 121 exposed by removing the seed layer CL may be also etched, so that a step difference is generated between an upper surface of the uppermost coreless circuit wire 121 and an upper surface of the uppermost insulating layer 111.

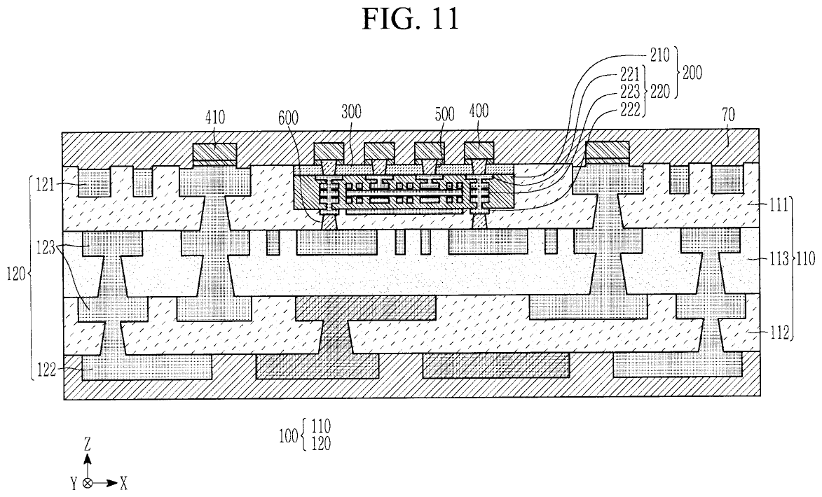

Next, as shown in FIG. 2 and FIG. 11, a solder resist layer 70 covering the bump pad 400 may be formed on the uppermost insulating layer 111 of the coreless substrate 100 (S800).

Next, as shown in FIG. 1 and FIG. 2, the solder resist pattern 700 in which a thickness of a portion of the solder resist layer 70 is reduced by removing a portion of the solder resist layer 70 by an exposure and etching process may be formed, so that upper surfaces of the bump pad 400 and the coreless pad 410 are exposed to the outside (S900). In this case, a solder resist opening 700a exposing the uppermost coreless circuit wire 121 and the lowermost coreless circuit wire 122 may be formed in the solder resist pattern 700. The uppermost coreless circuit wire 121 and the lowermost coreless circuit wire 122 may be in contact with a solder ball SB through the solder resist opening 700a.

The coreless interposer IS may be manufactured using the manufacturing method described above, so that the upper surface 300u of the adhesive member 300 is disposed on the same plane (the XY plane) as that of the upper surface 111u of the uppermost insulating layer 111. The bridge substrate 200 may be disposed within the uppermost insulating layer 111 among the plurality of insulating layers 110.

Unlike the embodiment shown in FIG. 1, another embodiment in which the bridge substrate further includes a dummy member is also possible.

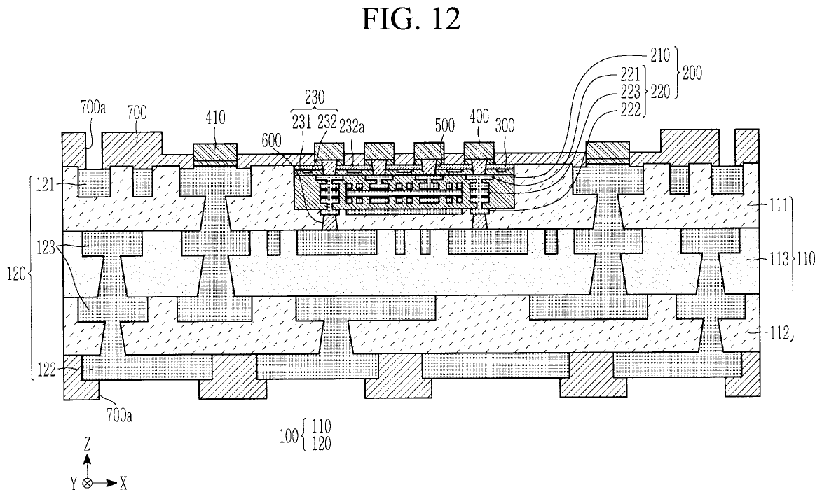

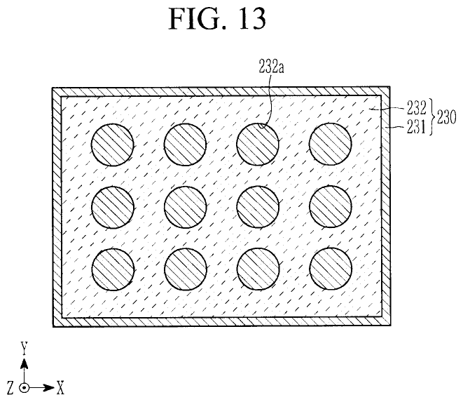

Hereinafter, a coreless interposer according to another embodiment of the present disclosure will be described in detail with reference to FIG. 12 and FIG. 13.

FIG. 12 is a cross-sectional view of the coreless interposer according to the other embodiment, and FIG. 13 is a plan view of a bridge substrate of FIG. 12.

The other embodiment illustrated in FIG. 12 and FIG. 13 is substantially the same as the embodiment illustrated in FIG. 1 except for a structure of a dummy member, so a repeated description thereof will be omitted.

As shown in FIG. 12 and FIG. 13, the coreless interposer according to the other embodiment of the present disclosure may include a coreless substrate 100, a bridge substrate 200, an adhesive member 300, a bump pad 400, a first bridge via 500, a second bridge via 600, and a solder resist pattern 700.

The bridge substrate 200 may include a bridge insulating layer 210, a plurality of bridge circuit wires 220, and a dummy member 230.

The plurality of bridge circuit wires 220 may include an uppermost bridge circuit wire 221, a lowermost bridge circuit wire 222, and an intermediate bridge circuit wire 223.

The dummy member 230 may include a dummy insulating layer 231 and a dummy wiring layer 232.

The dummy insulating layer 231 may cover the uppermost bridge circuit wire 221, and may be made of the same material as that of the bridge insulating layer 210. That is, the dummy insulating layer 231 may include an organic compound (e.g., a photosensitive organic compound such as a photo imageable dielectric (PID)).

The dummy wiring layer 232 may be embedded in the dummy insulating layer 231, and may not be electrically connected to the uppermost bridge circuit wire 221. The dummy wiring layer 232 may include a plurality of first penetration holes 232a at a position corresponding to the first bridge via 500. The first bridge via 500 may penetrate the plurality of first penetration holes 232a.

The bridge substrate 200 may enhance strength and rigidity of the bridge substrate 200 including an organic compound by including the dummy member 230 including the dummy insulating layer 231 and the dummy wiring layer 232.

Additionally, the bridge substrate 200 may be embedded in the dummy insulating layer 231 and may include the dummy wiring layer 232 that is not electrically connected to the uppermost bridge circuit wire 221, so that the bridge substrate 200 is electrically inspected using the lowermost bridge circuit wire 222.

That is, when the bridge substrate 200 is manufactured, the bridge insulating layer 210 and the plurality of bridge circuit wires 220 may be formed after the dummy member 230 is formed on a bridge carrier substrate (not shown). Thus, before the bridge substrate 200 is separated from the bridge carrier substrate (not shown), an electrical inspection of the plurality of bridge circuit wires 220 is possible using the lowermost bridge circuit wire 222 that is electrically disconnected from the bridge carrier substrate (not shown) by the dummy member 230.

Unlike the embodiment shown in FIG. 1, another embodiment further including a protective member is also possible.

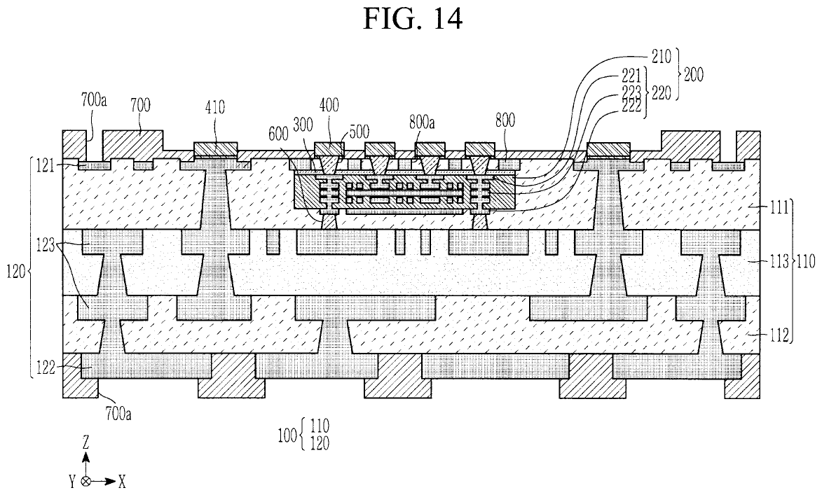

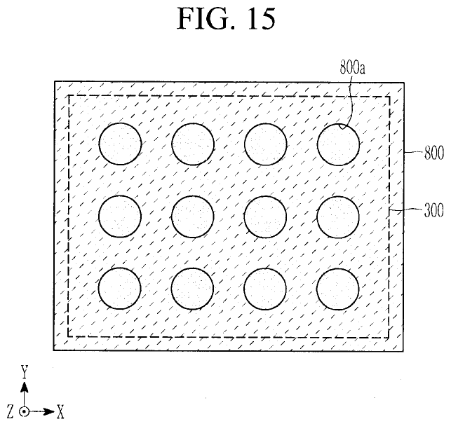

Hereinafter, a coreless interposer according to another embodiment of the present disclosure will be described in detail with reference to FIG. 14 and FIG. 15.

FIG. 14 is a cross-sectional view of the coreless interposer according to the other embodiment, and FIG. 15 is a plan view of a protective member of FIG. 14.

The other embodiment illustrated in FIG. 14 and FIG. 15 is substantially the same as the embodiment illustrated in FIG. 1 except for a structure of the protective member, so a repeated description thereof will be omitted.

As shown in FIG. 14 and FIG. 15, the coreless interposer according to the other embodiment of the present disclosure may include a coreless substrate 100, a bridge substrate 200, an adhesive member 300, a bump pad 400, a first bridge via 500, a second bridge via 600, a solder resist pattern 700, and a protective member 800.

The coreless substrate 100 may include a plurality of insulating layers 110 and a plurality of coreless circuit wires 120. The plurality of insulating layers 110 may include an uppermost insulating layer 111, a lowermost insulating layer 112, and an intermediate insulating layer 113. The plurality of coreless circuit wires 120 may include an uppermost coreless circuit wire 121, a lowermost coreless circuit wire 122, and an intermediate coreless circuit wire 123.

The bridge substrate 200 may include a bridge insulating layer 210 and a plurality of bridge circuit wires 220. The plurality of bridge circuit wires 220 may include an uppermost bridge circuit wire 221, a lowermost bridge circuit wire 222, and an intermediate bridge circuit wire 223.

The protective member 800 may cover the adhesive member 300, and may include a plurality of second penetration holes 800a at a position corresponding to the first bridge via 500. This protective member 800 may be formed of the same material in the same layer as the uppermost coreless circuit wire 121. In this case, the first bridge via 500 may penetrate the plurality of second penetration holes 800a.

The coreless interposer according to the other embodiment may enhance strength and rigidity of the bridge substrate 200 including an organic compound by forming the protective member 800 that covers the adhesive member 300 to protect the bridge substrate 200.

In the embodiment shown in FIG. 1, the bump pad is formed below the solder resist pattern and only an upper surface of the bump pad protrudes above the solder resist pattern, but another embodiment in which the bump pad is disposed above the solder resist pattern is also possible.

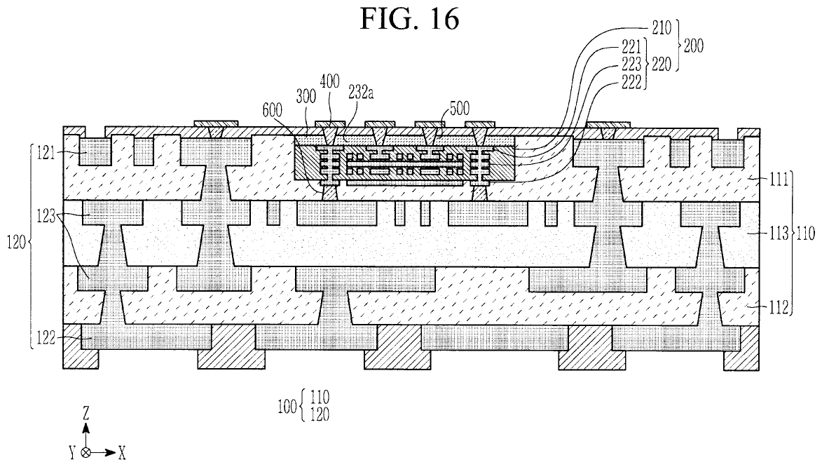

Hereinafter, a coreless interposer according to another embodiment of the present disclosure will be described in detail with reference to FIG. 16.

FIG. 16 is a cross-sectional view of the coreless interposer according to the other embodiment.

The other embodiment illustrated in FIG. 16 is substantially the same as the embodiment illustrated in FIG. 1 except for a structure of a bump pad, so a repeated description thereof will be omitted.

As shown in FIG. 16, the coreless interposer according to the other embodiment of the present disclosure may include a coreless substrate 100, a bridge substrate 200, an adhesive member 300, a bump pad 400, a first bridge via 500, a second bridge via 600, and a solder resist pattern 700.

The bridge substrate 200 may include a bridge insulating layer 210 and a plurality of bridge circuit wires 220. The plurality of bridge circuit wires 220 may include an uppermost bridge circuit wire 221, a lowermost bridge circuit wire 222, and an intermediate bridge circuit wire 223.

The adhesive member 300 may be disposed on an upper surface of the bridge substrate 200. In this case, an upper surface 300u of the adhesive member 300 may be disposed on the same plane as that of an upper surface 111u of an uppermost insulating layer 111.

The solder resist pattern 700 may cover the adhesive member 300, an uppermost coreless circuit wire 121, and the uppermost insulating layer 111.

The bump pad 400 may be disposed on the solder resist pattern 700, and may be electrically connected to the uppermost bridge circuit wire 221 through the first bridge via 500.

The first bridge via 500 may together penetrate the adhesive member 300 and the solder resist pattern 700, and may electrically connect the bump pad 400 and the uppermost bridge circuit wire 221.

In the other embodiment shown in FIG. 16, the bump pad is disposed on the solder resist pattern, but another embodiment in which in which a first bump pad is disposed below the solder resist pattern and a second bump pad is disposed on the solder resist pattern is also possible.

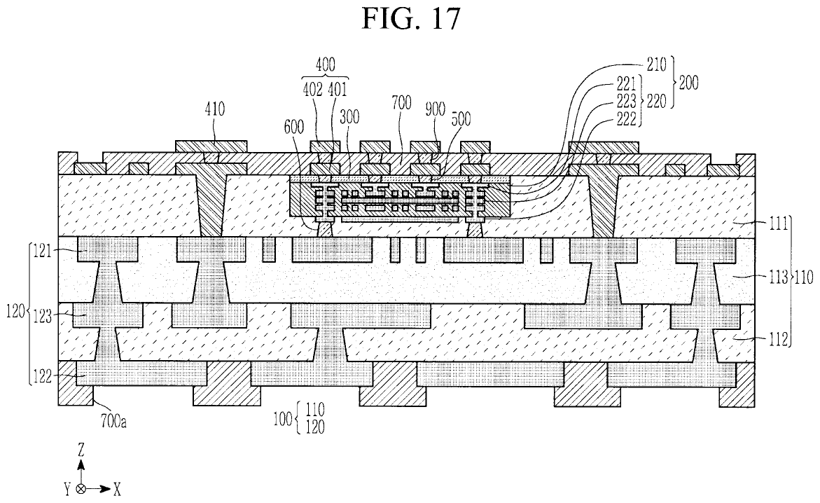

Hereinafter, a coreless interposer according to another embodiment of the present disclosure will be described in detail with reference to FIG. 17.

FIG. 17 is a cross-sectional view of the coreless interposer according to the other embodiment.

The other embodiment illustrated in FIG. 17 is substantially the same as the embodiment illustrated in FIG. 16 except for a structure of a bump pad, so a repeated description thereof will be omitted.

As shown in FIG. 17, the coreless interposer according to the other embodiment of the present disclosure may include a coreless substrate 100, a bridge substrate 200, an adhesive member 300, a bump pad 400, a first bridge via 500, a second bridge via 600, and a solder resist pattern 700.

The bridge substrate 200 may include a bridge insulating layer 210 and a plurality of bridge circuit wires 220. The plurality of bridge circuit wires 220 may include an uppermost bridge circuit wire 221, a lowermost bridge circuit wire 222, and an intermediate bridge circuit wire 223.

The adhesive member 300 may be disposed on an upper surface of the bridge substrate 200. In this case, an upper surface 300u of the adhesive member 300 may be disposed on the same plane as that of an upper surface 111u of an uppermost insulating layer 111.

A first bump pad 401 may be disposed on the adhesive member 300, and may be electrically connected to the uppermost bridge circuit wire 221 through the first bridge via 500.

The solder resist pattern 700 may cover the first bump pad 401, an uppermost coreless circuit wire 121, the uppermost insulating layer 111, and the adhesive member 300.

A second bump pad 402 may be disposed on the solder resist pattern 700, and may be electrically connected to the first bump pad 401 through a third bridge via 900.

Hereinafter, a semiconductor package including a coreless interposer according to an embodiment will be described in detail with reference to FIG. 18.

FIG. 18 is a side view of the semiconductor package including the coreless interposer according to the embodiment.

As shown in FIG. 18, the semiconductor package including the coreless interposer according to the embodiment may include a circuit board CB, a plurality of semiconductor chips SC, the coreless interposer IS, and a solder ball SB.

The plurality of semiconductor chips SC may be an integrated circuit dies disposed above the circuit board CB and in which hundreds to millions of elements are integrated into one chip. For example, the semiconductor chip SC may be a processor chip such as a central processor (e.g., a CPU), a graphic processor (e.g., a GPU), a field programmable gate array (FPGA), a digital signal processor, an encryption processor, a microprocessor, or a microcontroller, and specifically, the semiconductor chip SC may be an application processor (AP), but the present disclosure is not limited thereto. In addition, the semiconductor chip SC may be a memory such as a volatile memory (e.g., a DRAM), a non-volatile memory (e.g., a ROM), or a flash memory, or a logic such as an analog-digital converter or an application-specific IC (ASIC).

The coreless interposer IS may electrically connect the circuit board CB and the plurality of semiconductor chips SC. The coreless interposer IS may include the coreless substrate 100, the bridge substrate 200, the adhesive member 300, the bump pad 400, the first bridge via 500, the second bridge via 600, and the solder resist pattern 700.

Because the bridge substrate 200 disposed inside the coreless substrate 100 includes an organic compound, an ultra-fine circuit may be implemented within the coreless interposer IS of FIG. 18 with the bridge substrate 200 and simultaneously a mechanical property such as a modulus and a coefficient of thermal expansion (CTE) between the coreless substrate 100 and the bridge substrate 200 may be similar so that warpage or the like of the coreless interposer IS is minimized.

The solder ball SB may be made of a conductive material, and may be used to electrically connect the circuit board CB and the coreless interposer IS or to electrically connect the coreless interposer IS and the plurality of semiconductor chips SC.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A coreless interposer comprising:
a coreless substrate that includes a plurality of insulating layers and a plurality of coreless circuit wires disposed within the plurality of insulating layers; and
a bridge substrate that is disposed within the coreless substrate,
wherein the bridge substrate includes a bridge insulating layer including an organic compound and a plurality of bridge circuit wires disposed within the bridge insulating layer and having a wiring width less than that of the plurality of coreless circuit wires, and an uppermost bridge circuit wire among the plurality of bridge circuit wires is embedded in the bridge insulating layer.

2. The coreless interposer of claim 1, wherein an upper surface of the uppermost bridge circuit wire is disposed on a same plane as that of an upper surface of the bridge substrate.

3. The coreless interposer of claim 2, wherein a lowermost bridge circuit wire among the plurality of bridge circuit wires is a conductive pad protruding from a lower surface of the bridge substrate.

4. The coreless interposer of claim 3, wherein the plurality of insulating layers includes an uppermost insulating layer, a lowermost insulating layer, and an intermediate insulating layer disposed between the uppermost insulating layer and the lowermost insulating layer, and the bridge substrate is disposed within the uppermost insulating layer.

5. The coreless interposer of claim 4, wherein the uppermost insulating layer is free of a glass cloth, and the intermediate insulating layer includes a glass cloth.

6. The coreless interposer of claim 4, further comprising an adhesive member that is disposed on the upper surface of the bridge substrate,
wherein an upper surface of the adhesive member is disposed on a same plane as that of an upper surface of the uppermost insulating layer.

7. The coreless interposer of claim 6, further comprising a bump pad that is disposed above the adhesive member and is electrically connected to the uppermost bridge circuit wire.

8. The coreless interposer of claim 7, further comprising a first bridge via that penetrates the adhesive member and electrically connects the bump pad and the uppermost bridge circuit wire.

9. The coreless interposer of claim 8, further comprising a second bridge via that penetrates the uppermost insulating layer and electrically connects an intermediate coreless circuit wire disposed between an uppermost coreless circuit wire and a lowermost coreless circuit wire among the plurality of coreless circuit wires and the lowermost bridge circuit wire.

10. The coreless interposer of claim 9, further comprising a solder resist pattern that covers the uppermost coreless circuit wire and the uppermost insulating layer,
wherein the bump pad protrudes from an upper surface of the solder resist pattern.

11. The coreless interposer of claim 8, wherein the bridge substrate further includes a dummy member, and the dummy member includes a dummy insulating layer covering the uppermost bridge circuit wire and made of a same material as that of the bridge insulating layer and a dummy wiring layer embedded in the dummy insulating layer, not electrically connected to the uppermost bridge circuit wire, and including a plurality of first penetration holes.

12. The coreless interposer of claim 11, wherein the first bridge via penetrates the plurality of first penetration holes.

13. The coreless interposer of claim 8, further comprising a protective member that covers the adhesive member and includes a plurality of second penetration holes,
wherein the first bridge via penetrates the plurality of second penetration holes.

14. The coreless interposer of claim 6, further comprising:
a solder resist pattern that covers the adhesive member, an uppermost coreless circuit wire, and the uppermost insulating layer; and
a bump pad disposed on the solder resist pattern and electrically connected to the uppermost bridge circuit wire.

15. The coreless interposer of claim 6, further comprising:
a first bump pad disposed on the adhesive member and electrically connected to the uppermost bridge circuit wire;
a solder resist pattern that covers the first bump pad and the uppermost insulating layer; and
a second bump pad disposed on the solder resist pattern and electrically connected to the first bump pad.

16. A manufacturing method of a coreless interposer, comprising:
preparing a bridge substrate that includes a bridge insulating layer including an organic compound and a plurality of bridge circuit wires disposed within the bridge insulating layer;
adhering the bridge substrate to a carrier substrate using an adhesive member;
forming a coreless substrate that covers the bridge substrate and includes a plurality of coreless circuit wires having a wiring width greater than that of the plurality of bridge circuit wires; and
separating a portion of the carrier substrate from the coreless substrate,
wherein an uppermost bridge circuit wire among the plurality of bridge circuit wires is embedded in the bridge insulating layer.

17. The manufacturing method of claim 16, further comprising forming a seed circuit wire using a seed layer of the carrier substrate before the bridge substrate is adhered to the carrier substrate.

18. The manufacturing method of claim 17, further comprising:
forming a bump pad that is connected to the bridge circuit wire of the bridge substrate on the coreless substrate;
removing the seed layer;
forming a solder resist pattern covering the bump pad on the coreless substrate; and
removing a portion of a solder resist layer to expose the bump pad.

19. The manufacturing method of claim 18, wherein the forming of the coreless substrate covering the bridge substrate comprises:
forming the bridge substrate and an uppermost insulating layer covering the seed circuit wire; and
stacking an intermediate insulating layer covering the uppermost insulating layer and a lowermost insulating layer,
wherein the bridge substrate is disposed within the uppermost insulating layer.

20. A semiconductor package comprising:
a circuit board;
a plurality of semiconductor chips disposed above the circuit board; and
a coreless interposer that electrically connects the circuit board and the plurality of semiconductor chips,
wherein the coreless interposer includes a coreless substrate including a plurality of insulating layers and a plurality of coreless circuit wires disposed within the plurality of insulating layers and a bridge substrate disposed within the coreless substrate, the bridge substrate includes a bridge insulating layer including an organic compound and a plurality of bridge circuit wires disposed within the bridge insulating layer and having a wiring width less than that of the plurality of coreless circuit wires, and an uppermost bridge circuit wire among the plurality of bridge circuit wires is embedded in the bridge insulating layer.
